(19) United States
(12) Patent Application Publication
(10) Pub. No.: US 2026/0365770 A1
(43) Pub. Date: Nov. 19, 2026

(54) CURABLE COMPOSITION, CURED PRODUCT THEREOF, LED ELEMENT, ELECTRONIC DEVICE, AND OPTICAL ELEMENT

(71) Applicant: DIC Corporation, Tokyo (JP)

(72) Inventors: Yuichi Inoue, Kitaadachi-gun, Saitama (JP); Naohito Saito, Kitaadachi-gun, Saitama (JP)

(73) Assignee: DIC Corporation, Tokyo (JP)

(21) Appl. No.: 19/112,381

(22) PCT Filed: Sep. 21, 2023
(86) PCT No.: PCT/JP2023/034213

§ 371 Date: Mar. 17, 2025

(30) Foreign Application Priority Data
Oct. 3, 2022 (JP) 2022-159847
Jan. 20, 2023 (JP) 2023-007680

(51) Int. Cl. C08F 220/20; C08F 2/50; C08F 220/18; C08F 220/28; C08F 220/30; C08F 222/10; C08F 222/14; C09D 4/00; H10H 20/854

(52) U.S. Cl. CPC C08F 220/20; C08F 2/50; C08F 220/1809; C08F 220/1811; C08F 220/282; C08F 220/301; C08F 222/102; C08F 222/14; C09D 4/00; H10H 20/854

(57) ABSTRACT

Provided is a curable composition that has excellent curability and storage stability and can form a cured product having excellent heat resistance, lightfastness, moisture resistance, transparency, and adhesion to a substrate by an inkjet method. Provided is a curable composition containing, as essential components, a (meth)acrylate (a) having a hydroxy group and a monomer (c) having two or more (meth)acrylate groups. Provided are an LED sealing material as a cured product of the curable composition, an LED element including a cured product of the curable composition, and an electronic device and an optical element including a cured product of the curable composition.

### TECHNICAL FIELD

The present invention relates to a curable composition, a cured product of the curable composition, an LED element including the cured product, an electronic device including the cured product, and an optical element including the cured product.

### BACKGROUND ART

Display apparatuses such as liquid crystal displays, plasma displays, organic EL displays, and mini-LED displays are widely being used. In recent years, micro-LED displays, which have excellent characteristics such as luminance, color gamut, contrast, and reliability and can achieve lower power consumption by using a high-luminous efficiency LED as a light source, have been actively developed toward practical implementation.

From the viewpoint of maintaining the characteristics of light-emitting elements, various developments of sealing materials have been made. PTL 1 discloses a method of sealing an organic light-emitting material layer and electrodes constituting an organic EL display element with a laminate film of a silicon nitride film and a resin film formed by a CVD method in order to inhibit characteristics degradation due to water, oxygen, and the like in the organic EL element.

Heat generation in LED packages along with larger output of LEDs has become a problem, and silicone-based resins have been used as LED sealing materials instead of epoxy resins, which inevitably yellow. PTL 2 discloses a thermosetting resin composition containing a thermosetting resin containing a specific silsesquioxane and an organopolysiloxane, a cured product thereof, and a composition for an optical semiconductor containing the thermosetting resin composition.

### CITATION LIST

### Patent Literature

PTL 1: Japanese Unexamined Patent Application Publication No. 2000-223264
PTL 2: WO 2014/077216

### SUMMARY OF INVENTION

### Technical Problem

In electronic devices including light-emitting elements such as LEDs, such as backlights and displays, sealing materials are required to have characteristics such as transparency and adhesion as well as reliability such as heat resistance and lightfastness against heat generation in light-emitting elements and light emitted thereby and moisture resistance in highly humid environments. As the characteristics required for LED sealing materials are thus becoming stricter, there is a demand for sealing materials that can be ready for larger output of LEDs and higher performance of micro-LED displays and the like, have heat resistance, lightfastness, and moisture resistance, have excellent adhesion to a substrate, and are transparent, still leaving room for improvement.

Meanwhile, as to the composition itself as the sealing material, too, from the viewpoint of, in addition to production costs of compounds to be blended, consideration to the environment, readiness to thinner displays, and simplified production processes and improvement in safety, there is a demand for solvent-free compositions that can be applied by an inkjet method and do not require annealing treatment.

The inventors of the present invention have conducted intensive studies to find that a curable composition with a specific polymerizable monomer selected as a component has excellent curability and can form a formed product by an inkjet method and that a cured product to be obtained has excellent various properties such as heat resistance, lightfastness, moisture resistance, and transparency.

An object of the present invention is to provide a curable composition that has excellent curability and storage stability and can form a cured product having excellent heat resistance, lightfastness, moisture resistance, transparency, and adhesion to a substrate by an inkjet method.

Another object of the present invention is to provide an LED sealing material as a cured product of the curable composition, an LED element including a cured product of the curable composition, and an electronic device and an optical element including a cured product of the curable composition.

### Solution to Problem

The present invention has the following aspects:

[1] A curable composition containing, as essential components, a (meth)acrylate (a) having a hydroxy group and a monomer (c) having two or more (meth)acrylate groups.

[2] A curable composition containing, as essential components, components (a) to (c) below:
a (meth)acrylate (a) having a hydroxy group;
a (meth)acrylate (b) having a phosphoric acid group; and
a monomer (c) having two or more (meth)acrylate groups.

[3] The curable composition according to [1] or [2], further containing a (meth)acrylate (d) having a cyclic skeleton.

[4] The curable composition according to [3], in which the (meth)acrylate (d) having a cyclic skeleton is one or more selected from the group consisting of a (meth)acrylate (d1) having a cyclic skeleton containing a hetero atom and a (meth)acrylate (d2) having a carbocyclic skeleton.

[5] The curable composition according to any of [1] to [4], in which the curable composition contains the monomer (c) having two or more (meth)acrylate groups in an amount of 5 to 50% by mass with respect to a total mass of the composition.

[6] The curable composition according to any of [1] to [5], in which the monomer (c) having two or more (meth)acrylate groups is a monomer having three or more (meth)acrylate groups.

[7] The curable composition according to any of [1] to [6], in which the curable composition contains the (meth)acrylate (a) having a hydroxy group in an amount of 10 to 50% by mass with respect to a total mass of the composition.

[8] The curable composition according to any of [2] to [7], in which the curable composition contains the (meth)acrylate (b) having a phosphoric acid group in an amount of 0.01 to 10% by mass with respect to a total mass of the composition.

[9] The curable composition according to any of [1] to [8], further containing a photoinitiator.

[10] The curable composition according to any of [1] to [9], in which the curable composition is an active energy ray curable composition.

[11] The curable composition according to any of [1] to [10], in which the curable composition has a viscosity at 25 °C of 3 to 30 mPa·s.

[12] The curable composition according to any of [1] to [11], in which the curable composition does not contain a solvent.

[13] The curable composition according to any of [1] to [12], in which the curable composition is a composition for an LED sealing material.

[14] The curable composition according to any of [1] to [13], in which the curable composition is formed by an inkjet method.

[15] A cured product of the curable composition according to any of [1] to [14].

[16] The cured product according to [15], in which the cured product is an LED sealing material.

[17] An LED element including a cured product of the curable composition according to any of [1] to [14].

[18] An electronic device including a cured product of the curable composition according to any of [1] to [14].

[19] An optical element including a cured product of the curable composition according to any of [1] to [14].

### Advantageous Effects of Invention

The present invention can provide a curable composition that has excellent curability and storage stability and can form a cured product having excellent heat resistance, lightfastness, moisture resistance, transparency, and adhesion to a substrate by an inkjet method. The present invention can also provide an LED sealing material as a cured product of the curable composition, an LED element including a cured product of the curable composition, and an electronic device and an optical element including a cured product of the curable composition.

### BRIEF DESCRIPTION OF DRAWING

FIG. 1 is a diagram schematically illustrating a configuration example of a micro-LED display as an embodiment of an electronic device including a cured product of a curable composition of the present invention as a sealing material.

### DESCRIPTION OF EMBODIMENTS

The present invention is a curable composition containing, as essential components, a (meth)acrylate having a hydroxy group (a) and a monomer (c) having two or more (meth)acrylate groups.

In addition, the present invention is a curable composition containing the following components (a) to (c) as essential components.
a (meth)acrylate (a) having a hydroxy group;
a (meth)acrylate (b) having a phosphoric acid group; and
a monomer (c) having two or more (meth)acrylate groups.

In the following, the curable composition of the present invention is also referred to simply as the “present curable composition.”

The present curable composition suitably further contains a (meth)acrylate (d) having a cyclic skeleton, and the (meth)acrylate (d) having a cyclic skeleton is preferably one or more selected from the group consisting of a (meth)acrylate (d1) having a cyclic skeleton containing a hetero atom and a (meth)acrylate (d2) having an aromatic ring.

In the present specification, “(meth)acrylate” is a generic term for acrylate, methacrylate, and both. “(Meth)acrylic” is a generic term for acrylic, methacrylic, and both. The “(meth)acryloyloxy group” is a generic term for an acryloyloxy group, a methacryloyloxy group, and both.

The present curable composition has excellent curability and storage stability. From the present curable composition, a cured product having excellent heat resistance, lightfastness, moisture resistance, transparency, and adhesion to a substrate can be formed by an inkjet method.

The following describes the configuration of the present curable composition.

Examples of the (meth)acrylate (a) having a hydroxy group in the present curable composition include 2-hydroxyethyl (meth)acrylate, 2-hydroxypropyl (meth)acrylate, 2-hydroxybutyl (meth)acrylate, 4-hydroxybutyl (meth)acrylate, 2-ethylhexyl diglycol (meth)acrylate, diethylene glycol mono(meth)acrylate, 2-hydroxy-3-phenoxypropyl (meth)acrylate, 1,4-cyclohexanedimethanol monoacrylate, 1-(acryloyloxy)-3-(methacryloyloxy)-2-propanol, and pentaerythritol triacrylate. Among these, from the viewpoint of versatility, relatively inexpensive availability, good curability, inkjet ejection properties, and excellence in various properties such as the moisture resistance and heat resistance of the cured product after curing, 2-hydroxypropyl (meth)acrylate, 4-hydroxybutyl (meth)acrylate, and pentaerythritol triacrylate are preferred, and 4-hydroxybutyl acrylate is more preferred. Containing the (meth)acrylate (a) having a hydroxy group improves the moisture resistance and heat resistance of the cured product formed from the present curable composition.

The content of the (meth)acrylate (a) having a hydroxy group in the present curable composition is preferably 10% by mass or more, more preferably 158 by mass or more, and even more preferably 20% by mass or more with respect to the total mass of the present curable composition. The content of the (meth)acrylate (a) having a hydroxy group is preferably 50% by mass or less, more preferably 45% by mass or less, more preferably 40% by mass or less, and even more preferably 35% by mass or less with respect to the total mass of the present curable composition. In other words, the content of the (meth)acrylate (a) having a hydroxy group in the present curable composition is preferably in a range of 10 to 50% by mass, more preferably in a range of 15 to 45% by mass, more preferably in a range of 20 to 40% by mass, and even more preferably in a range of 20 to 35% by mass with respect to the total mass of the present curable composition.

When the present curable composition contains the (meth)acrylate (a) having a hydroxy group in such a range, the curability of the present curable composition is good, and the storage stability of the curable composition and the performance such as moisture resistance and heat resistance of the cured product after curing improve. In addition, the performance such as adhesion to a substrate of the cured product formed from the present curable composition improves.

Examples of the (meth)acrylate (b) having a phosphoric acid group in the present curable composition include phosphoric acid alkylene (meth)acrylates such as phosphoric acid methylene (meth)acrylate, phosphoric acid ethylene (meth)acrylate, phosphoric acid propylene (meth)acrylate, and phosphoric acid tetramethylene (meth)acrylate, phosphates of polyethylene glycol monoacrylate, phosphates of polypropylene glycol monomethacrylate, and compounds containing a phosphate represented by General Formula (b1) below.

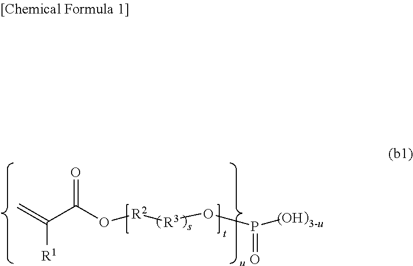

In Formula (b1), R¹ represents a hydrogen atom or a methyl group; R² represents a linear or branched alkylene group having one to four carbon atoms; R³ represents a divalent organic group; s is an integer of 0 to 3; t is an integer of 1 to 6; and u is an integer of 1 or 2.

R² in General Formula (b1) is preferably a linear or branched alkylene group having two or three carbon atoms, and examples thereof include a methylene group [—CH₂—], an ethylene group [—(CH₂)₂—], a trimethylene group [—(CH₂)₃—], —CH(CH₃)—, —CH(CH₂CH₃)—, and —C(CH₃)₂—.

Examples of the divalent organic group represented by R³ in General Formula (b1) include saturated or unsaturated divalent aliphatic hydrocarbon groups having one to 12 carbon atoms, divalent aromatic hydrocarbon groups having six to 12 carbon atoms, and divalent linking groups containing a hetero atom. These groups may have substituents. Examples of the substituent include a fluorine atom, fluorinated alkyl groups having one to five carbon atoms replaced with fluorine atoms, and a carbonyl group.

The divalent aliphatic hydrocarbon group may be linear or branched, and examples thereof include alkylene groups such as a methylene group, an ethylene group, a trimethylene group, a tetramethylene group [—(CH₂)₄—], and a pentamethylene group [—(CH₂)₅—]; and alkyl alkylene groups such as alkyl methylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkyl ethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyl trimethylene groups such as —CH(CH₃)CH₂CH₂— and —CH₂CH(CH₃)CH₂CH₂—; and alkyl tetramethylene groups such as —CH(CH₃)CH₂CH₂CH₂— and —CH₂CH(CH₃)CH₂CH₂—.

Examples of the divalent linking group containing a hetero atom include —O—, —C(═O)—O—, —O—C(═O)—, —C(═O)—, —O—C(═O)—O—, —C(═O)—NH—, —NH—, —S—, —S(═O)₂—, —S(═O)₂—O—.

Among these, R³ is preferably a linear or branched alkylene group, an ester bond [—C(═O)—O— or —O—C(═O)—], an ether bond (—O—), or a combination thereof.

The following shows specific examples of the (meth)acrylate (b) having a phosphoric acid group represented by General Formula (b1). In the chemical formulae, R¹ and u are as defined above.

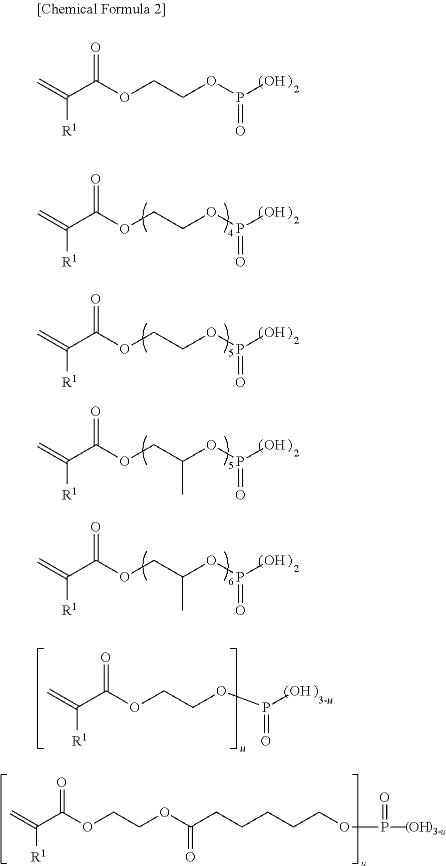

For the (meth)acrylate (b) having a phosphoric acid group, commercially available products can also be used, and examples thereof include the product name “EBECRYL168” manufactured by Daicel-Allnex Ltd., the product names “KAYAMER PM-2” and “KAYAMER PM-21” manufactured by Nippon Kayaku Co., Ltd., the product names “Phosmer M,” “Phosmer PE,” and “Phosmer PP” manufactured by Uni-Chemical, “Light Ester P-1M,” “Light Acrylate P-1A (N),” and “Light Ester P-2M” manufactured by Kyoeisha Chemical Co., Ltd., and “JPA-514” manufactured by Johoku Chemical Co., Ltd.

One type of the (meth)acrylate (b) having a phosphoric acid group may be used alone, or two or more types may be used in combination.

When the present curable composition contains the (meth)acrylate (b) having a phosphoric acid group, the content thereof is preferably 0.01% by mass or more, more preferably 0.02% by mass or more, more preferably 0.03% by mass or more, more preferably 0.05% by mass or more, more preferably 0.1% by mass or more, more preferably 0.2% by mass or more, and even more preferably 0.5% by mass or more with respect to the total mass of the present curable composition. The content of the (meth)acrylate (b) having a phosphoric acid group is preferably 10% by mass or less, more preferably 8% by mass or less, more preferably 8% by mass or less, more preferably 58 by mass or less, more preferably 3% by mass or less, more preferably 2% by mass or less, more preferably 18 by mass or less, and even more preferably 0.8% by mass or less with respect to the total mass of the present curable composition. In other words, when the present curable composition contains the (meth)acrylate (b) having a phosphoric acid group, the content thereof is preferably in a range of 0.01 to 10% by mass, more preferably in a range of 0.02 to 8% by mass, and even more preferably in a range of 0.03 to 5% by mass with respect to the total mass of the present curable composition.

When the present curable composition contains the (meth)acrylate (b) having a phosphoric acid group in such a range, the curability of the present curable composition is good, and the performance such as adhesion to a substrate of the cured product formed from the present curable composition improves.

Examples of the monomer (c) having two or more (meth)acrylate groups in the present curable composition include glycol di(meth)acrylates such as ethylene glycol di(meth)acrylate, 1,4-butanediol di(meth)acrylate, neopentyl glycol di(meth)acrylate, 3-methyl-1,5-pentanediol di(meth)acrylate, 1,6-hexanediol di(meth)acrylate, 1,9-nonanediol di(meth)acrylate, 2-methyl-1,8-octanediol di(meth)acrylate, 2-butyl-2-ethyl-1,3-propanediol di(meth)acrylate, tricyclodecanedimethanol di(meth)acrylate, ethoxylated (2) neopentyl glycol di(meth)acrylate [a di(meth)acrylated compound of a neopentyl glycol ethylene oxide 2 mol adduct], propoxylated (2) neopentyl glycol di(meth)acrylate [a di(meth)acrylated compound of a neopentyl glycol propylene oxide 2 mol adduct];
alkylene glycol di(meth)acrylates such as diethylene glycol di(meth)acrylate, triethylene glycol di(meth)acrylate, tetraethylene glycol di(meth)acrylate, polyethylene glycol di(meth)acrylate, dipropylene glycol di(meth)acrylate, tripropylene glycol di(meth)acrylate, tetrapropylene glycol di(meth)acrylate, polypropylene glycol di(meth)acrylate, polytetramethylene glycol di(meth)acrylate, and bis(4-acryloxypolyethoxyphenyl) propane;
di(meth)acrylate of tris(2-hydroxyethyl) isocyanurate;
dimethylol tricyclodecane di(meth)acrylate and caprolactone-modified neopentyl glycol hydroxypivalate di(meth)acrylate;
bisphenol A di(meth)acrylate, propylene oxide-modified bisphenol A type di(meth)acrylate, ethylene oxide-modified bisphenol A type di(meth)acrylate, bisphenol F di(meth)acrylate, propylene oxide-modified bisphenol F type di(meth)acrylate, and ethylene oxide-modified bisphenol F type di(meth)acrylate;
trifunctional (meth)acrylates such as pentaerythritol tri(meth)acrylate, trimethylolpropane tri(meth)acrylate, trimethylolpropane ethylene oxide-modified tri(meth)acrylate, trimethylolpropane propylene oxide-modified tri(meth)acrylate, tetramethylolmethane tri(meth)acrylate, modified glycerin tri(meth)acrylate, glycerin propylene oxide adduct tri(meth)acrylate, and glycerin ethylene oxide adduct tri(meth)acrylate;
tetrafunctional (meth)acrylates such as pentaerythritol tetra(meth)acrylate, dipentaerythritol tetra(meth)acrylate, ditrimethylolpropane tetra(meth)acrylate, and tetramethylolmethane tetra(meth)acrylate; and
hexafunctional (meth)acrylates such as dipentaerythritol hexa(meth)acrylate and caprolactone-modified dipentaerythritol hexa(meth)acrylate.

One type of the monomer (c) having two or more (meth)acrylate groups may be used alone, or two or more types may be used in combination.

The content of the monomer (c) having two or more (meth)acrylate groups in the present curable composition is preferably 58 by mass or more, more preferably 8% by mass or more, and even more preferably 108 by mass or more with respect to the total mass of the present curable composition. The content of the monomer (c) having two or more (meth)acrylate groups is preferably 50% by mass or less, more preferably 45% by mass or less, more preferably 40% by mass or less, more preferably 30% by mass or less, more preferably 20% by mass or less, and even more preferably 15% by mass or less with respect to the total mass of the present curable composition. In other words, the content of the monomer (c) having two or more (meth)acrylate groups in the present curable composition is preferably in a range of 5 to 50% by mass, more preferably in a range of 5 to 45% by mass, more preferably in a range of 5 to 40% by mass, more preferably in a range of 5 to 30% by mass, more preferably in a range of 5 to 20% by mass, and even more preferably in a range of 5 to 15% by mass with respect to the total mass of the present curable composition.

When the present curable composition contains the monomer (c) having two or more (meth)acrylate groups in such a range, the curability of the present curable composition is good, and the performance such as flexibility and adhesion to a substrate of the cured product formed from the present curable composition improves.

When one type of compound is used alone as the monomer (c) having two or more (meth)acrylate groups, for example, when a monomer having three or more (meth)acrylate groups, such as the trifunctional (meth)acrylate and the tetrafunctional (meth)acrylate exemplified above, such as trimethylolpropane ethylene oxide-modified triacrylate, is used, the performance such as flexibility and adhesion to a substrate of the cured product formed from the present curable composition can be effectively improved.

When two or more types of compounds are used in combination as the monomer (c) having two or more (meth)acrylate groups, too, it is preferable to use monomers having three or more (meth)acrylate groups, such as the trifunctional (meth)acrylate and the tetrafunctional (meth)acrylate exemplified above, in combination from the viewpoint of effectively improving the performance such as flexibility and adhesion to a substrate of the cured product formed from the present curable composition. In this case, the content of the monomer having three or more (meth)acrylate groups in the monomer (c) having two or more (meth)acrylate groups is preferably 10% by mass or more, and the entire amount may be the monomer having three or more (meth)acrylate groups.

The present curable composition may further contain the (meth)acrylate (d) having a cyclic skeleton. When the (meth)acrylate (d) having a cyclic skeleton is contained, it becomes easy to adjust the viscosity of the present curable composition to a viscosity range suitable for forming by the inkjet method. In addition, the cured product formed from the present curable composition has smaller shrinkage and has excellent adhesion and the like. From these points of view, it is preferable to further contain the (meth)acrylate (d) having a cyclic skeleton.

In the present specification, a (meth)acrylate having a hydroxy group and having a cyclic skeleton is classified as the (meth)acrylate (a) having a hydroxy group, and a (meth)acrylate having a phosphoric acid group and having a cyclic skeleton is classified as the (meth)acrylate (b) having a phosphoric acid group. A monomer having two or more (meth)acrylate groups is classified as the (meth)acrylate (a) having a hydroxy group or the (meth)acrylate (b) having a phosphoric acid group when it has either one or more hydroxy groups or phosphoric acid groups regardless of the presence or absence of a cyclic skeleton, and is classified as the monomer (c) having two or more (meth)acrylate groups when it has neither a hydroxy group nor a phosphoric acid group.

In other words, the (meth)acrylate (d) having a cyclic skeleton includes mono(meth)acrylates having a cyclic skeleton and having neither a hydroxy group nor a phosphoric acid group.

The (meth)acrylate (d) having a cyclic skeleton is preferably one or more selected from the group consisting of the (meth)acrylate (d1) having a cyclic skeleton containing a hetero atom and the (meth)acrylate (d2) having a carbocyclic skeleton.

Examples of the (meth)acrylates (d1) having a cyclic skeleton containing a hetero atom include (meth)acryloyl morpholine, N-(meth)acryloyloxyethyl hexahydrophthalimide, tetrahydrofurfuryl (meth)acrylate, and cyclic trimethylolpropane formal (meth)acrylate.

Examples of the (meth)acrylate (d2) having a carbocyclic skeleton include mono(meth)acrylates having a cyclic aliphatic group, such as cyclohexyl (meth)acrylate, 4-t-butylcyclohexyl (meth)acrylate, tricyclodecanedimethanol mono(meth)acrylate, adamantyl (meth)acrylate, cyclohexanedimethanol mono(meth)acrylate, trimethylcyclohexyl (meth)acrylate, isobornyl (meth)acrylate, t-butylcyclohexyl (meth)acrylate, dicyclopentanyl (meth)acrylate, and dicyclopentenyloxyethyl (meth)acrylate; and mono(meth)acrylates having an aromatic hydrocarbon group, such as 2-phenoxyethyl (meth)acrylate and benzyl (meth)acrylate.

One type of the (meth)acrylate (d) having a cyclic skeleton may be used alone, or two or more types may be used in combination. From the viewpoint of excellence in the heat resistance of the cured product after curing, it is preferable to contain the (meth)acrylate (d2) having a carbocyclic skeleton as the (meth)acrylate (d) having a cyclic skeleton. In particular, when the present curable composition does not contain the (meth)acrylate (b) having a phosphoric acid group but contains the (meth)acrylate (d) having a cyclic skeleton, the content of the (meth)acrylate (d2) having a carbocyclic skeleton in the (meth)acrylate (d) having a cyclic skeleton is preferably 50% by mass or more, and the entire amount may be the (meth)acrylate (d2) having a carbocyclic skeleton.

From the viewpoint of excellence in safety, versatility, relatively inexpensive availability, and excellence in various properties such as inkjet ejection properties, good curability, and the adhesion of the cured product after curing to a substrate, tetrahydrofurfuryl (meth)acrylate and cyclic trimethylolpropane formal (meth)acrylate are more preferred as the (meth)acrylate (d1) having a cyclic skeleton containing a hetero atom, and 2-phenoxyethyl (meth)acrylate, isobornyl (meth)acrylate, 3,3,5-trimethylcyclohexyl acrylate, and t-butylcyclohexyl acrylate are more preferred as the (meth)acrylate (d2) having a carbocyclic skeleton.

In addition, in the present curable composition, as the (meth)acrylate (d) having a cyclic skeleton, it is even more preferable to use two or more out of four compounds including tetrahydrofurfuryl acrylate, cyclic trimethylolpropane formal acrylate, 2-phenoxyethyl acrylate, and 3,3,5-trimethylcyclohexyl acrylate in combination.

When the present curable composition contains the (meth)acrylate (d) having a cyclic skeleton, the content thereof is preferably 30% by mass or more, more preferably 35% by mass or more, more preferably 40% by mass or more, more preferably 45% by mass or more, and even more preferably 50% by mass or more with respect to the total mass of the present curable composition. The content of the (meth)acrylate (d) having a cyclic skeleton is preferably 80% by mass or less, more preferably 75% by mass or less, even more preferably 70% by mass or less, still even more preferably 65% by mass or less, and particularly preferably 60% by mass or less with respect to the total mass of the present curable composition. In other words, when the present curable composition contains the (meth)acrylate (d) having a cyclic skeleton, the content thereof is preferably in a range of 30 to 80% by mass, more preferably in a range of 30 to 70% by mass, more preferably in a range of 40 to 70% by mass, more preferably in a range of 50 to 70% by mass, and even more preferably in a range of 50 to 65% by mass with respect to the total mass of the present curable composition.

When the present ink composition contains the (meth)acrylate (d) having a cyclic skeleton in such a range, the curability of the present curable composition is good, and its storage stability, the performance of the cured product to be formed, and the like improve.

When both the (meth)acrylate (d1) having a cyclic skeleton containing a hetero atom and the (meth)acrylate (d2) having a carbocyclic skeleton are contained as the (meth)acrylate (d) having a cyclic skeleton, the content ratio thereof is not limited to a particular ratio, and from the viewpoint of excellence in various properties such as inkjet ejection properties, good curability, and the adhesion of the cured product after curing to a substrate, the ratio of the (meth)acrylate (d1) having a cyclic skeleton containing a hetero atom is preferably 50% by mass or more, and from the viewpoint of more excellence in the heat resistance of the cured product after curing, the ratio of the (meth)acrylate (d2) having a carbocyclic skeleton in the (meth)acrylate (d) having a cyclic skeleton is preferably 50% by mass or more.

In particular, to obtain good inkjet ejection properties, good curability, and good adhesion of the cured product after curing to a substrate and excellent heat resistance of the cured product after curing in a balanced manner, the ratio of the (meth)acrylate (d2) having a carbocyclic skeleton in the (meth)acrylate (d) having a cyclic skeleton is preferably in a range of 20 to 70% by mass, more preferably in a range of 25 to 70% by mass, and even more preferably in a range of 30 to 65% by mass.

The present curable composition may further contain another polymerizable compound different from the (meth)acrylate (a) having a hydroxy group, the (meth)acrylate (b) having a phosphoric acid group, the monomer (c) having two or more (meth)acrylate groups, and the (meth)acrylate (d) having a cyclic skeleton. Examples of the other polymerizable compound include monofunctional polymerizable compounds and polymerizable compounds having two or more polymerizable groups (hereinafter referred to as the “polyfunctional polymerizable compound”). The polymerizable group means a group having a polymerizable unsaturated double bond.

The monofunctional polymerizable compound is preferably a compound that is liquid at 25 °C having the polymerizable unsaturated double bond, and its molecular weight is preferably 60 to 2,000, and more preferably 100 to 1,000. The viscosity of such a monofunctional polymerizable compound is preferably 1,000 mPa·s or less, and more preferably 300 mPa·s or less. Such viscosity is preferably 1 mPa·s or more, and more preferably 3 mPa·s or more.

Examples of the monofunctional polymerizable compound as the other polymerizable compound include polymerizable compounds having a heterocyclic structure, monofunctional (meth)acrylates having a chain-like aliphatic group, monofunctional (meth)acrylates having an alkyleneoxy group, and monovinyl ether compounds.

Examples of the polymerizable compound having a heterocyclic structure include N-vinylcaprolactam, N-vinylpyrrolidone, and N-vinylformamide.

Examples of the monofunctional (meth)acrylate having a chain-like aliphatic group include isoamyl (meth)acrylate, stearyl (meth)acrylate, lauryl (meth)acrylate, octyl (meth)acrylate, isooctyl (meth)acrylate, decyl (meth)acrylate, isomyristyl (meth)acrylate, and isostearyl (meth)acrylate.

Examples of the monofunctional (meth)acrylate having an alkyleneoxy group include methoxyethyl (meth)acrylate, ethoxyethyl (meth)acrylate, butoxyethyl (meth)acrylate, ethoxyethoxyethyl (meth)acrylate, diethylene glycol monobutyl ether (meth)acrylate, methoxydiethylene glycol (meth)acrylate, methoxytriethylene glycol (meth)acrylate, methoxypolyethylene glycol (meth)acrylate, and methoxypropylene glycol (meth)acrylate.

Examples of the monovinyl ether compound include ethylene glycol monovinyl ether, triethylene glycol monovinyl ether, hydroxyethyl monovinyl ether, ethyl vinyl ether, n-butyl vinyl ether, isobutyl vinyl ether, octadecyl vinyl ether, cyclohexyl vinyl ether, hydroxybutyl vinyl ether, 2-ethylhexyl vinyl ether, hydroxynonyl monovinyl ether, cyclohexane dimethanol monovinyl ether, n-propyl vinyl ether, isopropyl vinyl ether, isopropenyl vinyl ether, dodecyl vinyl ether, diethylene glycol monovinyl ether, phenyl glycidyl ether, butyl glycidyl ether, and 2-ethylhexyl glycidyl ether.

The polyfunctional polymerizable compound as the other polymerizable compound may be any of a monomer, an oligomer, and a polymer. In the present specification, the “monomer” means a compound with a molecular weight (or a weight average molecular weight in the case of having a molecular weight distribution) of 1,000 or less. The molecular weight (or the weight average molecular weight in the case of having a molecular weight distribution) of the monomer is 50 to 1,000. The “oligomer” means a polymerized body generally having a finite number (generally 5 to 100) of monomer-based constituents and having a weight average molecular weight greater than 1,000 and less than 30,000. The “polymer” means a polymerized body with a weight average molecular weight of 30,000 or more. The weight average molecular weight is a value measured by gel permeation chromatography (GPC) and determined as a value in terms of standard polystyrene.

Examples of the polyfunctional polymerizable compound include a monomer represented by General Formula (1) below:

CH₂=CR⁴—COO—R⁵—O—CH═CH—R⁶ (1)
(in the formula, R⁴ represents a hydrogen atom or a methyl group; R⁵ represents an organic residue having two to 20 carbon atoms; and R⁶ represents a hydrogen atom or an organic residue having one to 11 carbon atoms) (hereinafter simply referred to as the “monomer (1)”), divinyl ether compounds, trivinyl ether compounds, urethane (meth)acrylates, and amino (meth)acrylates.

In General Formula (1), examples of the organic residue having two to 20 carbons atoms represented by R⁵ include linear, branched, or cyclic alkylene groups having two to 20 carbon atoms, alkylene groups having two to 20 carbon atoms having an oxygen atom by an ether bond and/or an ester bond in the structure, and aromatic groups having six to 11 carbon atoms in which a hydrogen atom bonded to a carbon atom constituting the ring may be replaced with another substituent group. An alkylene group having two to six carbon atoms and an alkylene group having two to nine carbon atoms having an oxygen atom by an ether bond in the structure are preferred.

Examples of the organic residue having one to 11 carbon atoms represented by R⁶ include linear, branched, or cyclic alkyl groups having one to 10 carbon atoms and aromatic groups having six to 11 carbon atoms in which a hydrogen atom bonded to a carbon atom constituting the ring may be replaced with another substituent group. An alkyl group having one or two carbon atoms and an aromatic group having six to eight carbon atoms are preferred.

Specific examples of the monomer (1) include 2-vinyloxyethyl (meth)acrylate, 3-vinyloxypropyl (meth)acrylate, 1-methyl-2-vinyloxyethyl (meth)acrylate, 2-vinyloxypropyl (meth)acrylate, 4-vinyloxybutyl (meth)acrylate, 1-methyl-3-vinyloxypropyl (meth)acrylate, 1-vinyloxymethylpropyl (meth)acrylate, 2-methyl-3-vinyloxypropyl (meth)acrylate, 3-methyl-3-vinyloxypropyl (meth)acrylate, 1,1-dimethyl-2-vinyloxyethyl (meth)acrylate, 3-vinyloxybutyl (meth)acrylate, 1-methyl-2-vinyloxypropyl (meth)acrylate, 2-vinyloxybutyl (meth)acrylate, 4-vinyloxycyclohexyl (meth)acrylate, 5-vinyloxypentyl (meth)acrylate, 6-vinyloxyhexyl (meth)acrylate, 4-vinyloxymethylcyclohexylmethyl (meth)acrylate, p-vinyloxymethylphenylmethyl (meth)acrylate, 2-(vinyloxyethoxy)ethyl (meth)acrylate, 2-(vinyloxyisopropoxy)ethyl (meth)acrylate, 2-(vinyloxyethoxy)propyl (meth)acrylate, 2-(vinyloxyethoxy)isopropyl (meth)acrylate, 2-(vinyloxyisopropoxy)propyl (meth)acrylate, 2-(vinyloxyisopropoxy)isopropyl (meth)acrylate, 2-(vinyloxyethoxyethoxy)ethyl (meth)acrylate, 2-(vinyloxyethoxyisopropoxy)ethyl (meth)acrylate, 2-(vinyloxyethoxyisopropoxy)propyl (meth)acrylate, 2-(vinyloxyethoxyethoxy)isopropyl (meth)acrylate, 2-(vinyloxyethoxyisopropoxy)isopropyl (meth)acrylate, 2-(vinyloxyethoxyethoxyethoxy)ethyl (meth)acrylate, polyethylene glycol monovinyl ether (meth)acrylate, and polypropylene glycol monovinyl ether (meth)acrylate. As the monomer (1), from the viewpoint of having low viscosity, a high flash point, and excellent curability, 2-(2-vinyloxyethoxy)ethyl (meth)acrylate is preferred, and 2-(2-vinyloxyethoxy)ethyl acrylate is more preferred.

Examples of the divinyl ether compound or trivinyl ether compound include ethylene glycol divinyl ether, diethylene glycol divinyl ether, triethylene glycol divinyl ether, propylene glycol divinyl ether, dipropylene glycol divinyl ether, butanediol divinyl ether, hexanediol divinyl ether, cyclohexanedimethanol divinyl ether, and trimethylolpropane trivinyl ether.

Examples of the urethane (meth)acrylate include aliphatic urethane (meth)acrylates and aromatic urethane (meth)acrylates. The weight average molecular weight of the urethane (meth)acrylate is preferably 1,000 to 30,000, and more preferably 2,000 to 20,000. For the urethane (meth)acrylate, commercially available products can also be used, and examples thereof include U-2PPA, U-4HA, U-6HA, U-6LPA, U-15HA, U-324A, UA-122P, UA5201, and UA-512 manufactured by Shin-Nakamura Chemical Co., Ltd.; CN965NS, CN964A85, CN964, CN959, CN962, CN963J85, CN965, CN982B88, CN981, CN983, CN996, CN9002, CN9007, CN9009, CN9010, CN9011, CN9178, CN9788, and CN9893 manufactured by Sartomer; and EBECRYL230, EBECRYL270, EBECRYL8402, EBECRYL8804, EBECRYL8807, EBECRYL9270, and KRM8191 manufactured by Daicel-Allnex Ltd.

The amino (meth)acrylate is a (meth)acrylate amine-modified and having an amino group. The number average molecular weight of the amino (meth)acrylate is preferably 2,000 to 20,000, more preferably 2,000 to 10,000, and even more preferably 2,000 to 5,000. For the amino (meth)acrylate, commercially available products can also be used, and examples thereof include EBECRYL7100 and EBECRYL80 manufactured by Daicel-Allnex Ltd.

When the present curable composition further contains the other polymerizable compound, one type of the other polymerizable compound may be used alone, or two or more types may be used in combination. When the other polymerizable compound is further contained, the content thereof is preferably 30% by mass or less, more preferably 20% by mass or less, and from the viewpoint of easy adjustment of the viscosity of the present curable composition to be obtained and easy adjustment of the curing shrinkage of the cured product of the present curable composition, even more preferably 10% by mass or less with respect to the entire present curable composition.

The present curable composition may be a curable composition to be cured by heat or a curable composition to be cured by active energy rays. From the viewpoint of more suitable use as an LED sealing material, which will be described below, the present curable composition is preferably a curable composition to be cured by active energy rays. Thus, the present curable composition may further contain a photoinitiator and preferably contains the photoinitiator.

Examples of the photoinitiator include acylphosphine-based compounds such as 2-methylbenzoyldiphenylphosphine oxide, bis(2,6-dichlorobenzoyl)phenylphosphine oxide, phenylbis(2,4,6-trimethylbenzoyl)phosphine oxide, (2,4,6-trimethylbenzoyl)diphenylphosphine oxide, 2,6-dimethoxybenzoyldiphenylphosphine oxide, 2,6-dichlorobenzoyldiphenylphosphine oxide, bis(2,6-dichlorobenzoyl)-2,5-dimethylphenylphosphine oxide, bis(2,6-dichlorobenzoyl)-4-propylphenylphosphine oxide, bis(2,6-dichlorobenzoyl)-1-naphthylphosphine oxide, bis(2,6-dimethoxybenzoyl)phenylphosphine oxide, bis(2,6-dimethoxybenzoyl)-2,4,4-trimethylpentylphosphine oxide, and bis(2,6-dimethoxybenzoyl)-2,5-dimethylphenylphosphine oxide;
phosphinate-based compounds such as methyl (2,4,6-trimethylbenzoyl)phenylphosphinate, ethyl (2,4,6-trimethylbenzoyl)phenylphosphinate, methyl (3-benzoyl-2,4,6-trimethylbenzoyl)phenylphosphinate, ethyl (3-benzoyl-2,4,6-trimethylbenzoyl)phenylphosphinate, and isopropyl pivaloylphenylphosphinate;
benzoin isobutyl ether, 2,4-diethylthioxanthone [also called 2,4-diethylthioxanthen-9-one], 2-isopropylthioxanthone, methyl benzoylformate, 2-benzyl-2-dimethylamino-1-(4-morpholinophenyl)-butan-1-one, 1-hydroxycyclohexyl phenyl ketone, benzoin ethyl ether, benzyl dimethyl ketal, 2-hydroxy-2-methyl-1-phenylpropan-1-one, 1-(4-isopropylphenyl)-2-hydroxy-2-methylpropan-1-one, 2-methyl-1-(4-methylthiophenyl)-2-morpholinopropan-1-one, benzophenone, 4-phenylbenzophenone, isophthalphenone, 4-benzoyl-4′-methyldiphenyl sulfide, 2-(dimethylamino)-2-[(4-methylphenyl)methyl]-1-(4-morpholinophenyl)-butan-1-one), and 1-{4-[(4-benzoylphenyl) sulfanyl]phenyl}-2-methyl-2-[(4-methylphenyl) sulfonyl]propan-1-one.

Among these, preferred are phenylbis(2,4,6-trimethylbenzoyl)phosphine oxide, (2,4,6-trimethylbenzoyl)diphenylphosphine oxide, ethyl (2,4,6-trimethylbenzoyl)phenylphosphinate, and ethyl (3-benzoyl-2,4,6-trimethylbenzoyl)phenylphosphinate, which are ready for the wavelength of light emitted from a UV light-emitting diode (UV-LED) light source as the light source of active energy rays. In particular, when a UV-LED with a main peak wavelength of 365 to 405 nm is used as the light source, an acylphosphine-based compound, especially phenylbis(2,4,6-trimethylbenzoyl)phosphine oxide or (2,4,6-trimethylbenzoyl)diphenylphosphine oxide is preferably used as the photoinitiator.

One type of the photoinitiator may be contained alone, or two or more types may be contained.

When the present curable composition contains the photoinitiator, the content thereof is preferably 1 to 10% by mass, and more preferably 2 to 8% by mass with respect to the entire present curable composition. When the content of the photoinitiator is within the above range, the curability and storage stability of the present curable composition are good, the coloring of the cured product to be formed is inhibited, and the performance and the like of the cured product tend to improve.

When the present curable composition contains the photoinitiator, the present curable composition may further contain a sensitizer. Examples of the sensitizer include trimethylamine, methyl dimethanolamine, triethanolamine, p-diethylaminoacetophenone, ethyl p-dimethylamino benzoate, isoamyl p-dimethylamino benzoate, N,N-dimethyl benzylamine, 4,4′-bis(diethylamino)benzophenone, anthracene-9,10-diethyl ether, and 9,10-bis(n-heptanoyloxy) anthracene.

When the present curable composition contains the sensitizer, the content thereof is preferably 0.1 to 10% by mass, and more preferably 0.5 to 8% by mass with respect to the total mass of the present curable composition. When the content of the sensitizer is within the above range, the curability of the present curable composition is good, the coloring of the cured product to be formed is inhibited, and the performance and the like of the cured product tend to improve.

In addition to the components described above, the present curable composition may further contain a polymerization inhibitor such as hydroquinone, di-t-butylhydroquinone, p-methoxyphenol, benzoquinone, dibutylhydroxytoluene, a nitrosamine salt, a hindered amine-based compound, or 2,2,6,6-tetramethylpiperidine 1-oxyl (TEMPO) as needed. When the polymerization inhibitor is contained, the amount thereof is preferably in a range of 0.01 to 2% by mass with respect to the total amount of the present curable composition.

The present curable composition may contain an additive such as a surfactant, a UV absorber, an antioxidant, a surface tension modifier, an anti-fading agent, or a conductive salt. From the viewpoint of more improving adhesion to a base material such as a plastic base material, the present curable composition may also contain a non-reactive resin such as an acrylic resin, an epoxy resin, a terpene phenolic resin, or a rosin ester.

As described above, the present curable composition contains, as essential components, the (meth)acrylate (a) having a hydroxy group, the (meth)acrylate (b) having a phosphoric acid group, and the monomer (c) having two or more (meth)acrylate groups.

From the viewpoint that the curability and storage stability of the present curable composition are good, the coloring and shrinkage of the cured product formed from the present curable composition are inhibited, and performance such as adhesion to a substrate improves, the present curable composition further containing the (meth)acrylate (d) having a cyclic skeleton is preferred.

For the (meth)acrylate (a) having a hydroxy group, the (meth)acrylate (b) having a phosphoric acid group, the monomer (c) having two or more (meth)acrylate groups, and the (meth)acrylate (d) having a cyclic skeleton, compounds made from biomass materials may be used. In such a case, the present curable composition itself can be regarded as an environmentally friendly product, which is more preferred from the viewpoint of reducing environmental load.

From the viewpoint of inhibiting the shrinkage of the cured product of the present curable composition and making the performance such as adhesion to a substrate better, the ratio of the (meth)acrylate (d) having a cyclic skeleton to the total mass of the polymerizable compound components constituting the present curable composition, that is, the (meth)acrylate (a) having a hydroxy group, the (meth)acrylate (b) having a phosphoric acid group, the monomer (c) having two or more (meth)acrylate groups, the (meth)acrylate (d) having a cyclic skeleton, and the other polymerizable compound further contained as needed is preferably 30% by mass or more, more preferably 35% by mass or more, more preferably 40% by mass or more, more preferably 45% by mass or more, and even more preferably 50% by mass or more. Such a ratio is preferably 80% by mass or less, more preferably 75% by mass or less, even more preferably 70% by mass or less, still even more preferably 65% by mass or less, and particularly preferably 60% by mass or less. In other words, the ratio of the (meth)acrylate (d) having a cyclic skeleton to the total mass of the polymerizable compound components constituting the present curable composition is preferably in a range of 30 to 80% by mass, more preferably in a range of 30 to 70% by mass, more preferably in a range of 40 to 70% by mass, more preferably in a range of 50 to 70% by mass, and even more preferably in a range of 50 to 65% by mass.

When the ratio of the (meth)acrylate (d) having a cyclic skeleton is within the above range, curing shrinkage when the present curable composition is cured can be reduced, internal stress accumulated in the cured product can be reduced to prevent distortion, and adhesion at the interface between a base material and the cured product can be more ensured.

From the viewpoint of improving the curability of the present curable composition and making the properties such as adhesion to a substrate of the cured product of the present curable composition better, the ratio of the monomer (c) having two or more (meth)acrylate groups to the total mass of the polymerizable compound components constituting the present curable composition, that is, the (meth)acrylate (a) having a hydroxy group, the (meth)acrylate (b) having a phosphoric acid group, the monomer (c) having two or more (meth)acrylate groups, the (meth)acrylate (d) having a cyclic skeleton, and the other polymerizable compound further contained as needed is preferably 5% by mass or more, more preferably 8% by mass or more, and even more preferably 10% by mass or more. Such a ratio is preferably 65% by mass or less, more preferably 60% by mass or less, even more preferably 55% by mass or less, more preferably 50% by mass or less, more preferably 45% by mass or less, more preferably 40% by mass or less, more preferably 30% by mass or less, more preferably 20% by mass or less, and even more preferably 15% by mass or less. In other words, the ratio of the monomer (c) having two or more (meth)acrylate groups to the total mass of the polymerizable compound components constituting the present curable composition is preferably in a range of 5 to 65% by mass, preferably in a range of 5 to 50% by mass, more preferably in a range of 5 to 45% by mass, more preferably in a range of 5 to 40% by mass, more preferably in a range of 5 to 30% by mass, more preferably in a range of 5 to 20% by mass, and even more preferably in a range of 5 to 15% by mass.

The present curable composition may further contain an inorganic filler, various pigments and dyes, and the like from the viewpoint of applicability to uses in a wide range of industrial fields. Examples of the inorganic filler include carbon black, silicas, alumina, titanium oxide, zinc oxide, magnesium oxide, calcium carbonate, and talc.

The present curable composition may further contain a surfactant from the viewpoint of ensuring handleability and ejection stability applicable to the inkjet method and bringing the surface tension to a desired range. Examples of the surfactant include anionic surfactants such as dialkyl sulfosuccinates, alkylnaphthalene sulfonates, and fatty acid salts; nonionic surfactants such as polyoxyethylene alkyl ethers, polyoxyethylene alkyl allyl ethers, acetylene glycols, and polyoxyethylene-polyoxypropylene block copolymers; and cationic surfactants such as alkyl amine salts and quaternary ammonium salts.

As the surfactant, compounds having a silicone chain, silicone-based surfactants having a polyether chain in the side chain or the end and having a polysiloxane structure in the main chain, fluorine-based surfactants having a perfluoroalkyl chain, and preferably hydrophobic organic fluoro compounds such as oil-like fluorine-based compounds (e.g., fluorine oils) and solid fluorine compound resins (e.g., tetrafluoroethylene resins) may be used.

When the present curable composition further contains the surfactant, the content thereof is preferably 0.05 to 1% by mass, and more preferably 0.1 to 0.8% by mass with respect to the entire present curable composition.

The present curable composition may further contain a leveling agent. The leveling agent easily smooths the surface of the cured product formed from the curable composition, which facilitates uniform curing when the cured product is irradiated with UV rays, thus making unevenness less likely to occur in the cured product. Examples of the leveling agent include silane compounds, fluorine compounds, acrylic copolymers, and alcohol alkoxylate compounds. The surfactant described above can also be used as the leveling agent.

The viscosity at 25 °C of the present curable composition is preferably in a range of 3 to 30 mPa·s, and more preferably in a range of 5 to 20 mPa·s. The surface tension of the present curable composition is preferably in a range of 15 to 45 mN/m, more preferably in a range of 20 to 40 mN/m, and even more preferably in a range of 25 to 35 mN/m. The viscosity at 25 °C and the surface tension of the present curable composition being within the above ranges are preferable from the viewpoint that the handleability of the present curable composition and inkjet ejection stability during forming by the inkjet method can be improved.

Note that the present curable composition may further contain a solvent for the purpose of adjustment of the viscosity described above and the like to the extent that the effects of the present invention are not impaired, but it preferably does not contain any solvent. When the solvent is not contained, a drying step or heat treatment (annealing treatment) to remove the solvent can be omitted when the present curable composition is cured, and the production process can be simplified. In addition, curability is good, and outgas derived from the solvent is less likely to be generated from the cured product, which tends to improve safety. Thus, it is easy to obtain the present curable composition that can be applied by the inkjet method and does not require annealing treatment.

The present curable composition can be produced by, for example, supplying the (meth)acrylate (a) having a hydroxy group, the (meth)acrylate (b) having a phosphoric acid group, the monomer (c) having two or more (meth)acrylate groups, the (meth)acrylate (d) having a cyclic skeleton, and various optional additives as needed and stirring and mixing them together using an ordinary dispersing machine such as a bead mill or stirrer.

As the dispersing machine, in addition to a bead mill, various types of dispersing machines can be used, such as an ultrasonic homogenizer, a high-pressure homogenizer, a paint shaker, a ball mill, a roll mill, a sand mill, a sand grinder, a dyno mill, Dispermat, an SC mill, and Nanomizer, which are well-known and customary.

As described above, the present curable composition is preferably a curable composition to be cured by active energy rays. Examples of the active energy rays include visible rays, UV rays, infrared rays, microwaves, EUV, semiconductor laser light, and excimer lasers (KrF and ArF). Among these active energy rays, it is more preferred that the present curable composition is a curable composition to be cured by light irradiation such as UV rays.

As a light source of UV rays or the like, for example, a metal halide lamp, a xenon lamp, a carbon arc lamp, a chemical lamp, a low-pressure mercury lamp, a high-pressure mercury lamp, a UV-LED lamp, and the like can be used. From the viewpoint of extremely low heat generation and from the viewpoint of environmental protection that can be ready for being mercury-free, it is more preferred to cure by light irradiation using a UV-LED lamp, preferably a UV-LED lamp with a main peak wavelength of about 365 to 405 nm that can provide sufficient illumination as a light source.

The irradiation energy of light using the UV-LED is preferably in a range of 50 to 3,000 mJ/cm², and more preferably in a range of 200 to 2,000 mJ/cm².

The method of sealing a light-emitting element using the present curable composition as a sealing material is not limited to a particular method. Examples thereof include a method of dropping the present curable composition onto a light-emitting element, applying it thereto by a spin coater, a die coater, a dispenser, an inkjet method, a stencil printing method, a screen printing method, a gravure printing method, or through a mask, and then curing it; a method of injecting the present curable composition into a mold formwork by, for example, a dispenser, transfer molding, injection molding, or the like in advance, immersing therein a leadframe or the like to which a light-emitting element is fixed, and then curing it; a method of injecting the present curable composition into a formwork into which a light-emitting element is inserted and curing it; a method of injecting the present curable composition into a cup or the like in which a light-emitting element is placed at the bottom by a dispenser or the like and then curing it.

The present curable composition is applied to a release film using a coater or the like so as to have a thickness in a range from a submicron (0.1 μm) order to a several hundred micrometers order, and is then partially cured to once form a film or sheet in a semi-cured state. After transferring such a semi-cured film or sheet to a substrate to which a light-emitting element is fixed, it may be cured again to seal the light-emitting element.

Among them, forming by the inkjet method using an inkjet recording system is preferred. In this case, droplets of the present curable composition can be hit on a target with good positional accuracy, and thus the shape and dimensional accuracy of the cured product can be enhanced. In addition, compared to forming by a printing method involving contact, such as a screen printing method, when the present curable composition is formed by the inkjet method, foreign matter is less likely to be mixed into the present curable composition and its cured product, and the yield is less likely to deteriorate in producing sealed light-emitting elements.

As the inkjet recording system, any of conventionally known systems can be used, including, for example, a method using the vibration of a piezoelectric element to eject droplets (a recording method using an inkjet head forming ink droplets by the mechanical deformation of an electrostrictive element) and a method using thermal energy.

The cured product can be produced by ejecting and forming the present curable composition by the inkjet method and then curing it by irradiating it with active energy rays, which are suitably UV rays.

The present curable composition is suitable as a composition for sealing materials for light-emitting elements such as organic EL elements and LED elements, and is more suitable as a composition for an LED sealing material. That is, an aspect of the present invention is an LED element including the cured product of the present curable composition. In particular, the present curable composition can be suitably used as a sealing material for a micro-LED element.

An electronic device including the cured product of the present curable composition is also an aspect of the present invention. Using the cured product of the present curable composition can enhance the dimensional and shape accuracy of the electronic device and demonstrate the properties of the cured product of the present curable composition.

Examples of the electronic device include displays including light-emitting elements such as LED elements, micro-LED elements, organic EL elements, and organic light-emitting elements (OLEDs), display apparatuses such as mobile terminals, watches, and monitors, touch panels and lighting, conductive films, organic semiconductor devices, solar cells, organic solar cells, organic photoconductors (OPCs), and organic transistors.

A cured product having a concavo-convex shape, such as a lens shape, can also be produced using the present curable composition. That is, an optical element including the cured product of the present curable composition is also an aspect of the present invention.

Examples of the optical element include light guide plates with microlenses formed on their surfaces in liquid crystal backlight apparatuses and portable terminals such as smartphones. Using the cured product of the present curable composition can enhance the dimensional and shape accuracy of the optical element and demonstrate the properties of the cured product of the present curable composition.

Specifically, a microlens having excellent dimensional accuracy in terms of lens diameter and lens height on the order of 10 μm in diameter can be produced by ejecting and forming the present curable composition by the inkjet method and then irradiating it with active energy rays to cure it. Alternatively, an electroforming mold is produced from a microlens negative using the cured product of the present curable composition, and using the electroforming mold, a molded product (an optical element) having a microlens microstructure on the surface can also be produced.

The uses of the present curable composition are not limited only to the electronic device and the optical element. The present curable composition can be used in order to produce various products that take advantage of its properties.

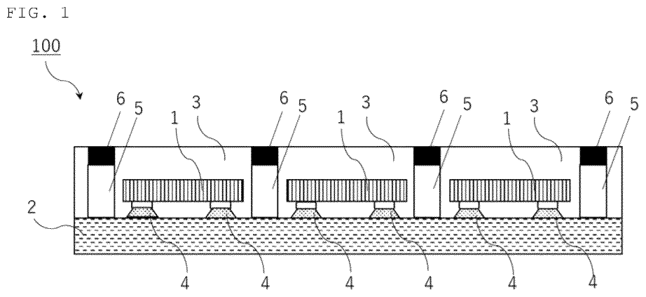

FIG. 1 schematically illustrates an example of the configuration of a micro-LED display, which is an electronic device including the cured product of the present curable composition, but this is not limiting. For example, the present curable composition can also be used in the display disclosed in U.S. Pat. No. 10,978,626 and the like.

In FIG. 1, this micro-LED display 100 includes a substrate 2, a micro-LED element 1 installed on the substrate 2, a sealing material 3, a junction 4 between the micro-LED element 1 and a metal wiring section (not shown) formed on the surface of the substrate 2, a partition 5, and a black layer 6 covering the top of the partition 5.

The micro-LED display 100 includes a plurality of the micro-LED elements 1, and in the micro-LED elements 1, adjacent micro-LED elements 1 are separated from each other by the partition 5 on the substrate 2. The sealing material 3 is the cured product of the present curable composition. As the substrate 2, for example, a transparent inorganic material such as glass or a film made of a heat-resistant resin material such as polyethylene naphthalate, polyamide, or polyimide can be used. The thickness of the substrate 2 is not limited to a particular thickness, and from the viewpoint of balancing heat resistance, insulation, production costs, and the like, a range of 25 to 125 μm is usually preferred in the case of the film.

The micro-LED display 100 can be produced, for example, as follows. First, the substrate 2 is prepared, and the micro-LED elements 1 are mounted on one face of this substrate 2. Subsequently, the partition 5 is produced on one face of the substrate 2 by a photolithographic method or an inkjet method using, for example, a photosensitive resin material. The present curable composition is then formed by, for example, an inkjet method to produce a coating film, and then the coating film of the present curable composition is irradiated with UV rays to cure it, thereby producing the sealing material 3. Irradiating of the coating film of the present curable composition with UV rays may be performed under an oxygen-containing atmosphere such as an atmospheric atmosphere or under an inert atmosphere such as a nitrogen atmosphere.

The thickness of the sealing material 3 in the micro-LED display 100 is usually preferably in a range of 5 to 100 μm, and more preferably in a range of 10 to 50 μm. By making the sealing material 3 thinner, the micro-LED display 100 can be made thinner and can also be provided with flexibility. Note that the thickness of the sealing material 3 refers to the distance from the outermost surface of the sealing material 3 or an interface with a facing base material to the outermost surface or the other facing interface on the other side.

One embodiment of the present curable composition, the cured product of the present curable composition, the LED element including the cured product, and the electronic device including the cured product have been described, but the present invention is not limited to the configuration of the embodiment described above. For example, the present curable composition may additionally have any other configuration or may be replaced with any configuration that produces a similar effect in the configuration of the above embodiment.

### EXAMPLES

The following specifically describes the present invention with reference to examples and comparative examples, but the present invention is not limited by these examples and the like.

The following shows compounds used in the present examples and the like.

### <(Meth)Acrylate (a) Having Hydroxy Group>

a-1: 4-HBA (product name, manufactured by Osaka Organic Chemical Industry Ltd., 4-hydroxybutyl acrylate)

a-2: HPA (product name, manufactured by Osaka Organic Chemical Industry Ltd., hydroxypropyl acrylate)

a-3: Miramer M340 (product name, manufactured by MIWON, pentaerythritol triacrylate)

### < (Meth)Acrylate (b) Having Phosphoric Acid Group>

b-1: KAYAMER PM-2 (product name, manufactured by Nippon Kayaku Co., Ltd.)

b-2: Light Acrylate P-1A (N) (product name, manufactured by Kyoeisha Chemical Co., Ltd., 2-acryloyloxyethyl acid phosphate)

### <Monomer (c) Having Two or More (Meth)Acrylate Groups>

c-1: Miramer M240 (product name, manufactured by MIWON, ethylene oxide-modified bisphenol A type diacrylate)

c-2: Miramer M3130 (product name, manufactured by MIWON, trimethylolpropane ethylene oxide-modified triacrylate)

c-3: Miramer M210 (product name, manufactured by MIWON, neopentyl glycol hydroxypivalate diacrylate)

c-4: Miramer M360 (product name, manufactured by MIWON, trimethylolpropane propylene oxide-added triacrylate)

### <(Meth)Acrylate (d1) Having Cyclic Skeleton Containing Hetero Atom>

d1-1: Viscoat 150 (product name, manufactured by Osaka Organic Chemical Industry Ltd., tetrahydrofurfuryl acrylate)

d1-2: Viscoat 200 (product name, manufactured by Osaka Organic Chemical Industry Ltd., cyclic trimethylolpropane formal acrylate)

### <(Meth)Acrylate (d2) Having Carbocyclic Skeleton>

d2-1: Light acrylate PO-A (product name, manufactured by Kyoeisha Chemical Co., Ltd., phenoxyethyl acrylate)

d2-2: isobornyl acrylate (manufactured by Osaka Organic Chemical Industry Ltd.)

d2-3: Viscoat 196 (product name, manufactured by Osaka Organic Chemical Industry Ltd., 3,3,5-trimethylcyclohexyl acrylate)

d2-4: Miramer M1150 (product name, manufactured by MIWON, t-butyl cyclohexyl acrylate)

### <Photoinitiator>

TPO-H: (2,4,6-trimethylbenzoyl)diphenylphosphine oxide; (manufactured by IGM RESINS B.V.)

Omnirad 819: phenylbis(2,4,6-trimethylbenzoyl)phosphine oxide (acylphosphine oxide-based; manufactured by IGM RESINS B.V.)

### <Polymerization Inhibitor>

Nonflex Alba: 2,5-di-t-butyl hydroquinone (manufactured by Seiko Chemical Co., Ltd.)

### <Additive (Leveling Agent)>

KF-352: polyether-modified polysiloxane (manufactured by Shin-Etsu Chemical Co., Ltd.)

### Production Examples 1 to 21

### 1. Preparation of Curable Composition

In accordance with the blending ratios listed in Table 1, the components were put into a container and stirred and mixed together to prepare curable compositions 1 to 21.

### 2. Evaluation

### 2-1. Viscosity of Curable Composition

Measurement was performed at 25 °C using an E-type viscometer (TVE-25L: manufactured by Toki Sangyo Co., Ltd.). Table 1 lists the viscosity of each curable composition with the following evaluation indicators.

### [Evaluation Indicators]

A: 20 mPa·s or less

B: Greater than 20 mPa·s and 30 mPa·s or less

C: Greater than 30 mPa·s

When each curable composition was stored at −20 to 20 °C, the viscosity change was small, and storage stability was good in all the examples.

### 2-2. Light Transmittance of Cured Product

(1) The curable composition obtained in each production example was applied to an alkali-free glass substrate (35 mm long×35 mm wide, 0.7 mm thick) using a spin coater with a film thickness of 10 μm to form a coating film. This coating film was irradiated with UV rays using a UV-LED irradiation apparatus (manufactured by Aitec System Co., Ltd.) at a peak wavelength of 385 nm, a peak illuminance of 500 mW/cm², and an integrated light amount of 3 J/cm² to cure it, producing a cured product (a cured coating film). Each cured product was substantially transparent.

(2) The light transmittance at wavelengths of 400 to 800 nm of each cured product obtained above was measured using a spectrometer (“LCD-5200” manufactured by Otsuka Electronics Co., Ltd.). Note that the measured value of the light transmittance of only the alkali-free glass substrate used in the production of the cured product was used as a reference value.

Table 1 lists the light transmittance value at 550 nm of each cured product.

### 2-3. Adhesion of Cured Product

In the same manner as in 2-2 (1), a cured product (a cured coating film) of the curable composition obtained in each production example was produced, and a cross-shaped cut was made on its surface using a cutter. Next, adhesive tape (manufactured by Nichiban Co., Ltd.) was applied over the cross-shaped cut and was then removed.

Further, new adhesive tape was applied over the same cross-shaped cut as above, and the operation of peeling it off was repeated a total of five times. For each operation, the presence or absence of peeling of the cured coating film from the alkali-free glass substrate after the adhesive tape was removed was visually observed, and adhesion was evaluated as follows.

### [Evaluation Criteria]

A: There was no peeling of the cured coating film.

B: Peeling of the cured coating film occurred at the third peeling or later.

C: Peeling of the cured coating film was observed at the first or second peeling.

### 2-4. Heat Resistance of Cured Product

In the same manner as in 2-2 (1), a cured product (a cured coating film) of the curable composition obtained in each production example was prepared. Each cured product was placed in a clean oven (manufactured by Espec Corporation) at 120 °C to perform aging for 500 hours, and a light transmittance after aging was measured by the 2-2 procedure. b* was calculated from the measurement result of the light transmittance spectrum, and heat resistance was evaluated on the following evaluation criteria. Note that b* refers to the degree of change in a tint, and a higher positive value means a stronger yellow tint.

### [Evaluation Criteria]

A: 0≤b*<1

B: 1≤b*<2

C: 2≤b*

### 2-5. Lightfastness of Cured Product

In the same manner as in 2-2 (1), a cured product (a cured coating film) of the curable composition obtained in each production example was prepared, and each cured product was placed in a sun test apparatus (manufactured by ATLAS Material Testing Technology Gmbh, CPS+, 765 W/m², 50 °C) and was irradiated with light equivalent to sunlight for 500 hours. A light transmittance after irradiation was measured by the 2-2 procedure, b* was calculated from the difference in the light transmittance before and after irradiation, and lightfastness was evaluated on the following evaluation criteria. Note that the meaning of b* is the same as that in 2-4.

### [Evaluation Criteria]

A: 0≤b*<1

B: 1≤b*<2

C: 2≤b*

### 2-6. Moisture Resistance of Cured Product

In the same manner as in 2-2 (1), a cured product (a cured coating film) of the curable composition obtained in each production example was prepared, and each cured product was placed in a thermostatic chamber at 85 °C and 85% relative humidity for 500 hours. After the cured product was taken out and cooled naturally to 25 °C, its surface was observed under a microscope (a magnification of 100-power) for the presence or absence of the occurrence of inhomogeneity, and moisture resistance was evaluated on the following criteria.

### [Evaluation Criteria]

A: No change

B: Inhomogeneity of the cured product surface was partially observed.

C: Inhomogeneity of the cured product surface can be visually observed without the need for microscopic observation.

Table 1 collectively lists the blending ratios of the curable compositions and the evaluation results described above. Table 1 also lists the ratio of the monomer (c) having two or more (meth)acrylate groups to the mass of the entire polymerizable compound (monomer (c) ratio; % by mass) and the ratio of the (meth)acrylate (d) having a cyclic skeleton to the mass of the entire polymerizable compound ((meth)acrylate (d) ratio; % by mass) in the curable composition of each production example.

TABLE 1

| | | | | Production Example | | | | | | | | | | |
|---|---|---|---|---|---|---|---|---|---|---|---|---|---|---|
| | | | | 1 | 2 | 3 | 4 | 5 | 6 | 7 | 8 | 9 | 10 | 11 |
| Curable composition No. | | | | 1 | 2 | 3 | 4 | 5 | 6 | 7 | 8 | 9 | 10 | 11 |
| Configuration | | | Abbr. | | | | | | | | | | | |
| % | Polymerizable | (Meth)acrylate | a-1 | 30.0 | 23.0 | 9.1 | 18.0 | 19.0 | 30.0 | 35.0 | 31.0 | 17.0 | 29.0 | 8.0 |
| by | compound | (a) | a-2 | | | 30.0 | | | | | | | | |
| mass | | having | a-3 | | | | | | | | | | | |
| | | hydroxy | | | | | | | | | | | | |
| | | group | | | | | | | | | | | | |
| | | (Meth)acrylate | b-1 | 0.5 | | 0.5 | 1.0 | 2.0 | 0.5 | 1.0 | 1.0 | | 0.2 | 0.5 |
| | | (b) | b-2 | | 5.0 | | | | | | | | | |
| | | having | | | | | | | | | | | | |
| | | phosphoric | | | | | | | | | | | | |
| | | acid group | | | | | | | | | | | | |
| | | Monomer (c) | c-1 | 6.0 | 4.0 | | 10.0 | 6.0 | | | | 5.0 | 4.0 | |
| | | having two | c-2 | 5.0 | 4.0 | 6.0 | 5.0 | 3.0 | 7.0 | 5.0 | 9.7 | | | 4.0 |
| | | or more | c-3 | | | | 26.0 | | | 6.7 | | | | 55.0 |
| | | (meth)acrylate | c-4 | | | 6.0 | | 13.0 | 6.0 | | | 6.0 | | |
| | | groups | | | | | | | | | | | | |
| | | (Meth)acrylate | d1-1 | 18.2 | 18.0 | 23.2 | 6.0 | 19.7 | 13.7 | | | | 16.5 | 20.2 |
| | | (d1) | d1-2 | | 10.7 | | 13.7 | 30.0 | | 3.0 | | | | |
| | | having | | | | | | | | | | | | |
| | | cyclic | | | | | | | | | | | | |
| | | skeleton | | | | | | | | | | | | |
| | | containing | | | | | | | | | | | | |
| | | hetero atom | | | | | | | | | | | | |
| | | (Meth)acrylate | d2-1 | 35.0 | 28.0 | 7.9 | | | | | | 64.7 | 43.0 | 5.0 |
| | | (d2) | d2-2 | | | | | | | 42.0 | | | | |
| | | having | d2-3 | | | 10.0 | 10.0 | | 35.5 | | 51.0 | | | |
| | | carbocyclic | d2-4 | | | | | | | | | | | |
| | | skeleton | | | | | | | | | | | | |

| | Photoinitiator (TPO-H) | 5.0 | 5.0 | 5.0 | 5.0 | 5.0 | 5.0 | 5.0 | 5.0 | 5.0 | 5.0 | 5.0 |
|---|---|---|---|---|---|---|---|---|---|---|---|---|
| | Photoinitiator | | 2.0 | 2.0 | 5.0 | 2.0 | 2.0 | 2.0 | 2.0 | 2.0 | 2.0 | 2.0 |
| | (Omnirad 819) | | | | | | | | | | | |
| | Polymerization | 0.1 | 0.1 | 0.1 | 0.1 | 0.1 | 0.1 | 0.1 | 0.1 | 0.1 | 0.1 | 0.1 |
| | inhibitor (Nonflex | | | | | | | | | | | |
| | Alba) | | | | | | | | | | | |
| | Leveling agent (KF- | 0.2 | 0.2 | 0.2 | 0.2 | 0.2 | 0.2 | 0.2 | 0.2 | 0.2 | 0.2 | 0.2 |
| | 352) | | | | | | | | | | | |
| Total of components | | 100.0 | 100.0 | 100.0 | 100.0 | 100.0 | 100.0 | 100.0 | 100.0 | 100.0 | 100.0 | 100.0 |
| | Monomer (c) ratio¹⁾ | 11.6 | 8.6 | 12.9 | 45.7 | 23.7 | 14.0 | 12.6 | 10.5 | 11.9 | 4.3 | 63.6 |
| | (Meth)acrylate (d) | 56.2 | 61.2 | 44.3 | 33.1 | 53.6 | 53.1 | 48.5 | 55.0 | 69.8 | 64.2 | 27.2 |
| | ratio²⁾ | | | | | | | | | | | |
| Evaluation | Viscosity of curable | A | A | A | A | A | A | A | A | A | A | A |
| | composition | | | | | | | | | | | |
| | Light transmittance | 99 | 99 | 99 | 99 | 99 | 99 | 99 | 99 | 99 | 99 | 99 |
| | of cured product | | | | | | | | | | | |
| | Substrate adhesion of | A | A | A | A | A | A | A | A | C | B | B |
| | cured product | | | | | | | | | | | |
| | Heat resistance of | A | A | A | A | A | A | A | A | A | B | A |
| | cured product | | | | | | | | | | | |
| | Lightfastness of | A | A | A | A | A | A | A | A | A | A | A |
| | cured product | | | | | | | | | | | |
| | Moisture resistance | A | A | A | A | A | A | A | A | B | B | B |
| | of cured product | | | | | | | | | | | |

| | | | | Production Example | | | | | | | | | |
|---|---|---|---|---|---|---|---|---|---|---|---|---|---|
| | | | | 12 | 13 | 14 | 15 | 16 | 17 | 18 | 19 | 20 | 21 |
| Curable composition No. | | | | 12 | 13 | 14 | 15 | 16 | 17 | 18 | 19 | 20 | 21 |
| Configuration | | | Abbr. | | | | | | | | | | |
| % | Polymerizable | (Meth)acrylate | a-1 | 7.0 | 23.0 | 31.0 | 21.0 | 21.0 | 31.0 | 15.0 | 31.0 | 17.0 | 31.0 |
| by | compound | (a) | a-2 | | | | | 10.0 | | 6.0 | | | |
| mass | | having | a-3 | | | | | | | | | 10.0 | |
| | | hydroxy | | | | | | | | | | | |
| | | group | | | | | | | | | | | |
| | | (Meth)acrylate | b-1 | | 0.02 | | | | | | | | |
| | | (b) | b-2 | 0.5 | | | | | | | | | |
| | | having | | | | | | | | | | | |
| | | phosphoric | | | | | | | | | | | |
| | | acid group | | | | | | | | | | | |
| | | Monomer (c) | c-1 | 4.0 | | | 2.0 | | | | | | |
| | | having two | c-2 | 4.0 | 9.7 | 9.7 | | | 9.7 | 9.7 | 9.7 | 5.0 | 9.7 |
| | | or more | c-3 | | | | | | | | | | |
| | | (meth)acrylate | c-4 | | | | 8.0 | 9.7 | | 3.5 | | | |
| | | groups | | | | | | | | | | | |
| | | (Meth)acrylate | d1-1 | 19.0 | | | | | | | | | |
| | | (d1) | d1-2 | | | | | 21.0 | 9.7 | 9.7 | | 20.7 | 34.0 |
| | | having | | | | | | | | | | | |
| | | cyclic | | | | | | | | | | | |
| | | skeleton | | | | | | | | | | | |
| | | containing | | | | | | | | | | | |
| | | hetero atom | | | | | | | | | | | |
| | | (Meth)acrylate | d2-1 | 33.7 | 10.0 | 10.0 | | | 32.6 | 21.0 | | 20.0 | |
| | | (d2) | d2-2 | 12.0 | | | | | | | | | |
| | | having | d2-3 | 12.5 | 50.0 | 42.5 | 61.7 | 31.0 | 9.7 | 27.8 | 10.7 | 20.7 | 18.7 |
| | | carbocyclic | d2-4 | | | | | | | | 42.0 | | |
| | | skeleton | | | | | | | | | | | |

| | Photoinitiator (TPO-H) | 5.0 | 5.0 | 5.0 | 5.0 | 5.0 | 5.0 | 5.0 | 5.0 | 5.0 | 5.0 |
|---|---|---|---|---|---|---|---|---|---|---|---|
| | Photoinitiator | 2.0 | 2.0 | 1.7 | 2.0 | 2.0 | 2.0 | 2.0 | 1.3 | 1.3 | 1.4 |
| | (Omnirad 819) | | | | | | | | | | |
| | Polymerization | 0.1 | 0.1 | 0.1 | 0.1 | 0.1 | 0.1 | 0.1 | 0.1 | 0.1 | 0.1 |
| | inhibitor (Nonflex | | | | | | | | | | |
| | Alba) | | | | | | | | | | |
| | Leveling agent (KF- | 0.2 | 0.2 | | 0.2 | 0.2 | 0.2 | 0.2 | 0.2 | 0.2 | 0.1 |
| | 352) | | | | | | | | | | |
| Total of components | | 100.0 | 100.0 | 100.0 | 100.0 | 100.0 | 100.0 | 100.0 | 100.0 | 100.0 | 100.0 |
| | Monomer (c) ratio¹⁾ | 8.6 | 10.5 | 10.4 | 10.8 | 10.5 | 10.5 | 14.2 | 10.4 | 5.4 | 10.4 |
| | (Meth)acrylate (d) | 83.3 | 64.7 | 56.3 | 66.6 | 56.1 | 56.1 | 63.1 | 56.4 | 65.7 | 56.4 |
| | ratio²⁾ | | | | | | | | | | |
| Evaluation | Viscosity of curable | A | A | A | A | A | A | A | A | A | A |
| | composition | | | | | | | | | | |
| | Light transmittance | 99 | 99 | 99 | 99 | 99 | 99 | 99 | 99 | 99 | 99 |
| | of cured product | | | | | | | | | | |
| | Substrate adhesion of | B | A | A | B | A | B | A | A | A | A |
| | cured product | | | | | | | | | | |
| | Heat resistance of | B | A | A | A | A | A | A | B | A | A |
| | cured product | | | | | | | | | | |
| | Lightfastness of | A | A | A | A | A | A | A | A | A | A |
| | cured product | | | | | | | | | | |
| | Moisture resistance | B | A | A | A | A | A | A | A | A | A |
| | of cured product | | | | | | | | | | |

¹⁾the mass ratio of monomer (c) in polymerizable compound
²⁾the mass ratio of (meth)acrylate (d) in polymerizable compound

These results show that when the curable composition contains, as essential components, the (meth)acrylate (a) having a hydroxy group and the monomer (c) having two or more (meth)acrylate groups and does not contain the (meth)acrylate (b) having a phosphoric acid group, and when it further contains the (meth)acrylate (d) having a cyclic skeleton, curability is excellent, and the transparency, adhesion to a substrate, heat resistance, lightfastness, and moisture resistance of the cured product are excellent. In particular, when the ratio of the (meth)acrylate (d2) having a carbocyclic skeleton in the (meth)acrylate (d) having a cyclic skeleton is 50% by mass or more, the cured product to be obtained has more excellent heat resistance (Production Examples 13 to 21).

When the curable composition contains, as essential components, the (meth)acrylate (a) having a hydroxy group, the (meth)acrylate (b) having a phosphoric acid group, and the monomer (c) having two or more (meth)acrylate groups, when the (meth)acrylate (a) having a hydroxy group is 10% by mass or more and the (meth)acrylate (b) having a phosphoric acid group is 0.01% by mass or more with respect to the total mass of the curable composition, the curable composition giving especially good adhesion of the cured product to a substrate can be obtained (Production Examples 1 to 8).

In addition, suitably, when the ratio of the (meth)acrylate (d) having a cyclic skeleton to the total mass of the polymerizable compound components constituting the curable composition, that is, the (meth)acrylate (a) having a hydroxy group, the (meth)acrylate (b) having a phosphoric acid group, the monomer (c) having two or more (meth)acrylate groups, the (meth)acrylate (d) having a cyclic skeleton, and the other polymerizable compound further contained as needed is in a range of 30 to 80% by mass, the cured product to be obtained is excellent in the above various properties such as adhesion to a substrate, heat resistance, lightfastness, and moisture resistance in a more balanced manner.

### INDUSTRIAL APPLICABILITY

The curable composition of the present invention has excellent curability and can form a formed product by the inkjet method, and the cured product to be obtained has excellent various properties such as heat resistance, lightfastness, moisture resistance, and transparency. The curable composition of the present invention is particularly suitable as a composition for an LED sealing material and is useful as a sealing material for micro-LED elements. In addition, the electronic device including the cured product of the present curable composition is useful as various display apparatuses, touch panels and lighting, conductive films, organic semiconductor devices, solar cells, organic solar cells, organic photoconductors (OPCs), organic transistors, and the like. The optical element including the cured product of the present curable composition is useful as, for example, components of liquid crystal backlight apparatuses and portable terminals such as smartphones.

### REFERENCE SIGNS LIST

1 micro-LED element
2 substrate
3 sealing material
4 junction
5 partition
6 black layer
100 micro-LED display

1. A curable composition comprising, as essential components, a (meth)acrylate (a) having a hydroxy group and a monomer (c) having two or more (meth)acrylate groups.

2. A curable composition comprising, as essential components, components (a) to (c) below:
a (meth)acrylate (a) having a hydroxy group;
a (meth)acrylate (b) having a phosphoric acid group; and
a monomer (c) having two or more (meth)acrylate groups.

3. The curable composition according to claim 1, further comprising a (meth)acrylate (d) having a cyclic skeleton.

4. The curable composition according to claim 3, wherein the (meth)acrylate (d) having a cyclic skeleton is one or more selected from the group consisting of a (meth)acrylate (d1) having a cyclic skeleton containing a hetero atom and a (meth)acrylate (d2) having a carbocyclic skeleton.

5. The curable composition according to claim 1, wherein the curable composition contains the monomer (c) having two or more (meth)acrylate groups in an amount of 5 to 50% by mass with respect to a total mass of the composition.

6. The curable composition according to claim 1, wherein the monomer (c) having two or more (meth)acrylate groups is a monomer having three or more (meth)acrylate groups.

7. The curable composition according to claim 1, wherein the curable composition contains the (meth)acrylate (a) having a hydroxy group in an amount of 10 to 50% by mass with respect to a total mass of the composition.

8. The curable composition according to claim 2, wherein the curable composition contains the (meth)acrylate (b) having a phosphoric acid group in an amount of 0.01 to 10% by mass with respect to a total mass of the composition.

9. The curable composition according to claim 1, further comprising a photoinitiator.

10. The curable composition according to claim 1, wherein the curable composition is an active energy ray curable composition.

11. The curable composition according to claim 1, wherein the curable composition has a viscosity at 25 °C of 3 to 30 mPa·s.

12. The curable composition according to claim 1, wherein the curable composition does not contain a solvent.

13. The curable composition according to claim 1, wherein the curable composition is a composition for an LED sealing material.

14. The curable composition according to claim 1, wherein the curable composition is formed by an inkjet method.

15. A cured product of the curable composition according to claim 1.

16. The cured product according to claim 15, wherein the cured product is an LED sealing material.

17. An LED element comprising a cured product of the curable composition according to claim 1.

18. An electronic device comprising a cured product of the curable composition according to claim 1.

19. An optical element comprising a cured product of the curable composition according to claim 1.
